(19) United States
(12) Patent Application Publication
(10) Pub. No.: US 2009/0091039 A1
(43) Pub. Date: Apr. 9, 2009

(54) SEMICONDUCTOR DEVICE, METHOD OF MANUFACTURING THE SAME, AND SEMICONDUCTOR SUBSTRATE

(75) Inventor: Toshitaka Akahoshi, Shiga (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/137,578

(22) Filed: Jun. 12, 2008

(30) Foreign Application Priority Data
Oct. 3, 2007 (JP) 2007-259297
Feb. 19, 2008 (JP) 2008-036748

(51) Int. Cl. H01L 23/48; H01L 21/00

(52) U.S. Cl. 257/773; 438/113; 257/E23.01; 257/E21.001

(57) ABSTRACT

According to the present invention, for collective molding of semiconductor devices, a semiconductor substrate includes first electrodes formed on the front side, second electrodes formed on the back side and connected to external electrode terminals, and a plurality of semiconductor element mounting regions 203. Along partition lines 202 for partitioning the semiconductor substrate into the plurality of semiconductor element mounting regions 203, recessed portions 205 are formed on the partition lines 202 on the front side of the semiconductor substrate.

### FIELD OF THE INVENTION

The present invention relates to a semiconductor device manufactured by collective molding, a method of manufacturing the same, and a semiconductor substrate for the collective molding of the semiconductor device.

### BACKGROUND OF THE INVENTION

Conventionally, in a typical resin molded semiconductor device, a semiconductor element is mounted on a substrate made of resin and is molded with thermosetting resin while being set in molding dies. Further, a surface of the substrate on which the semiconductor element is mounted is molded with resin, that is, only one surface of the substrate is molded with resin.

Moreover, in order to efficiently produce semiconductor devices by collective molding used as resin molding, a semiconductor substrate is divided along predetermined partition lines after resin molding. Thus desired semiconductor devices can be obtained in the same production facilities.

In a conventional semiconductor device (e.g., see Japanese Patent Laid-Open No. 2000-124163 as a Japanese patent laid-open publication), in order to improve the productivities, semiconductor elements are mounted in a plurality of semiconductor element mounting regions divided on a semiconductor substrate, the semiconductor element mounting surface of the substrate is molded with resin so as to simultaneously cover at least two of the semiconductor element mounting regions, and then the semiconductor substrate is divided along partition lines for partitioning the substrate into the plurality of semiconductor element mounting regions. In this method of manufacturing the semiconductor device, through holes are formed like slits along the partition lines, thereby suppressing side effects such as exfoliation of a package.

In the conventional semiconductor device, however, the through holes provided on the semiconductor substrate bring molding resin into contact not only with the semiconductor element mounting regions but also with a lower molding die which comes into contact with the back side of the semiconductor substrate through the through holes, during collective molding using molding dies.

Further, the back side of the semiconductor substrate may have an uneven surface because of a warp occurring over the substrate, a wiring pattern formed on the back side to connect external electrode terminals, and so on. Thus a gap may occur between the lower die and the semiconductor substrate.

When such a gap occurs, resin burrs may occur on the back side of the semiconductor substrate during resin molding, cause a defective appearance, and increase contamination in the molding dies. In some cases, the productivity may be reduced by lower yields and an increased number of steps, so that a product may become less reliable and the cost may increase.

### DISCLOSURE OF THE INVENTION

The present invention is devised to solve the above-described problems of the prior art. An object of the present invention is to provide a semiconductor device, a method of manufacturing the same, and a semiconductor substrate whereby even when a semiconductor device is manufactured by collective molding, it is possible to eliminate a defective appearance of a product and reduce the number of steps in a manufacturing process to suppress an increase in the cost of the product while preventing a crack and exfoliation of a package to improve the reliability of the product.

In order to solve the problem, a semiconductor device of the present invention is configured such that a semiconductor element having a plurality of electrodes for external connection is mounted on the front side of a semiconductor substrate having first electrodes formed on the front side and second electrodes formed on the back side, the electrodes for external connection on the front side of the semiconductor element and the first electrodes are electrically connected to each other, the front side of the semiconductor substrate is entirely covered with molding resin, and a plurality of external electrode terminals are connected to the second electrodes, wherein the semiconductor substrate has recessed portions formed on the edge of the front side of the semiconductor substrate.

Further, a semiconductor device of the present invention in which a semiconductor element having a plurality of electrodes for external connection is mounted on the front side of a semiconductor substrate having first electrodes formed on the front side and second electrodes formed on the back side, the electrodes for external connection on the front side of the semiconductor element and the first electrodes are electrically connected to each other, the front side of the semiconductor substrate is entirely covered with molding resin, and a plurality of external electrode terminals are connected to the second electrodes, wherein the semiconductor substrate has an edge formed on the front side of the semiconductor substrate such that the molding resin has a larger thickness on the edge of the semiconductor substrate than on other portions.

A semiconductor device of the present invention in which a semiconductor substrate having a multilayer structure made up of a first layer having first electrodes formed on the front side, a third layer having second electrodes formed on the back side, and a second layer disposed between the first layer and the third layer, a semiconductor element having a plurality of electrodes for external connection is mounted on the front side of the first layer, the electrodes for external connection on the front side of the semiconductor element and the first electrodes are electrically connected to each other, the semiconductor substrate has a front side entirely covered with molding resin, and a plurality of external electrode terminals are connected to the second electrodes, wherein the first layer has an area larger than the area of the second layer and smaller than the area of the third layer in the semiconductor substrate.

A method of manufacturing a semiconductor device of the present invention includes the steps of: mounting semiconductor elements in a plurality of semiconductor element mounting regions of a semiconductor substrate partitioned by partition lines into the semiconductor element mounting regions for mounting the semiconductor elements; molding the semiconductor element mounting surface of the semiconductor substrate with resin so as to simultaneously cover at least two of the semiconductor element mounting regions; and dividing the semiconductor substrate into semiconductor devices by dividing the semiconductor substrate into the plurality of semiconductor element mounting regions along the partition lines, wherein the method further includes the step of forming, along the partition lines, recessed portions on the partition lines on the front side of the semiconductor substrate before the resin molding.

A semiconductor substrate of the present invention includes, for collective molding of semiconductor devices, first electrodes formed on the front side, second electrodes formed on the back side and connected to external electrode terminals, and a plurality of semiconductor element mounting regions, wherein the semiconductor substrate further includes recessed portions formed on partition lines on the front side of the semiconductor substrate, along the partition lines for partitioning the semiconductor substrate into the plurality of semiconductor element mounting regions.

A semiconductor device of the present invention in which a semiconductor element having a plurality of electrodes for external connection is mounted on the front side of a semiconductor substrate having first electrodes formed on the front side and second electrodes formed on the back side, the electrodes for external connection on the semiconductor element and the first electrodes are electrically connected to each other, the front side of the semiconductor substrate is entirely covered with molding resin, and a plurality of external electrode terminals are connected to the second electrodes, wherein in the case where the first electrodes are disposed between the center of the semiconductor substrate and the central point of the side end face of the semiconductor element and the edge of the semiconductor substrate, the front side of the semiconductor substrate is formed such that in a region which is parallel to the side width of the semiconductor element and ranges from the side end face of the semiconductor element to the edge of the semiconductor substrate on the front side of the semiconductor substrate, a region surface area ranging from the first electrodes to the edge of the semiconductor substrate is larger than a region surface area ranging from the side end face of the semiconductor element to the first electrodes.

A semiconductor device of the present invention in which a semiconductor element having a plurality of electrodes for external connection is mounted on the front side of a semiconductor substrate having first electrodes formed on the front side and second electrodes formed on the back side, the electrodes for external connection on the semiconductor element and the first electrodes are electrically connected to each other, the front side of the semiconductor substrate is entirely covered with molding resin, and a plurality of external electrode terminals are connected to the second electrodes, wherein in the case where the first electrodes are disposed between the edge of the semiconductor substrate and the central point of the side end face of the semiconductor element and the edge of the semiconductor substrate, the front side of the semiconductor substrate is formed such that in a region which is parallel to the side width of the semiconductor element and ranges from the side end face of the semiconductor element to the edge of the semiconductor substrate on the front side of the semiconductor substrate, a region surface area ranging from the central point to the edge of the semiconductor substrate is larger than a region surface area ranging from the side end face of the semiconductor element to the central point.

A semiconductor device of the present invention in which a semiconductor element having a plurality of electrodes for external connection is mounted on the front side of a semiconductor substrate having first electrodes formed on the front side and second electrodes formed on the back side, the electrodes for external connection on the semiconductor element and the first electrodes are electrically connected to each other, the front side of the semiconductor substrate is entirely covered with molding resin, and a plurality of external electrode terminals are connected to the second electrodes, wherein in the case where the first electrodes are disposed between the center of the semiconductor substrate and the central point of the side end face of the semiconductor element and the edge of the semiconductor substrate, the front side of the semiconductor substrate is formed such that in a direction substantially perpendicular to the side of the semiconductor element from the side end face of the semiconductor element to the edge of the semiconductor substrate on the front side of the semiconductor substrate, a surface distance from the first electrodes to the edge of the semiconductor substrate is longer than a surface distance from the side end face of the semiconductor element to the first electrodes.

A semiconductor device of the present invention in which a semiconductor element having a plurality of electrodes for external connection is mounted on the front side of a semiconductor substrate having first electrodes formed on the front side and second electrodes formed on the back side, the electrodes for external connection on the semiconductor element and the first electrodes are electrically connected to each other, the front side of the semiconductor substrate is entirely covered with molding resin, and a plurality of external electrode terminals are connected to the second electrodes, wherein in the case where the first electrodes are disposed between the edge of the semiconductor substrate and the central point of the side end face of the semiconductor element and the edge of the semiconductor substrate, the front side of the semiconductor substrate is formed such that in a direction substantially perpendicular to the side of the semiconductor element from the side end face of the semiconductor element to the edge of the semiconductor substrate on the front side of the semiconductor substrate, a surface distance from the central point to the edge of the semiconductor substrate is longer than a surface distance from the side end face of the semiconductor element to the central point.

As described above, according to the present invention, the molding resin has a larger thickness on the edge of the semiconductor device than on a portion around the center of the semiconductor device, so that the molding resin clamps the semiconductor substrate from the edge to the center. Consequently, it is possible to increase a resistance to a crack and exfoliation of a package.

Thus even when a semiconductor device is manufactured by collective molding, it is possible to eliminate a defective appearance of a product and reduce the number of steps in a manufacturing process to suppress an increase in the cost of the product while preventing a crack and exfoliation of the package to improve the reliability of the product.

### BRIEF DESCRIPTION OF THE DRAWINGS

FIG. 1 is a sectional view showing a first structural example of a semiconductor device according to an embodiment of the present invention;

FIG. 2 is a sectional view showing a second structural example of the semiconductor device according to the embodiment of the present invention;

FIG. 3 is a sectional view showing a third structural example of the semiconductor device according to the embodiment of the present invention;

FIG. 4 is a plan view showing a fourth structural example of the semiconductor device according to the embodiment of the present invention;

FIG. 5 is a sectional view showing a fifth structural example of the semiconductor device according to the embodiment of the present invention;

FIG. 6 is a plan view showing a structural example of the semiconductor device according to the embodiment of the present invention;

FIG. 7A is a sectional view showing a manufacturing step (a) in a method of manufacturing the semiconductor device according the embodiment of the present invention;

FIG. 7B is a sectional view showing a manufacturing step (b) in the method of manufacturing the semiconductor device according the embodiment of the present invention;

FIG. 7C is a sectional view showing a manufacturing step (c) in the method of manufacturing the semiconductor device according the embodiment of the present invention;

FIG. 7D is a sectional view showing a manufacturing step (d) in the method of manufacturing the semiconductor device according the embodiment of the present invention;

FIG. 7E is a sectional view showing a manufacturing step (e) in the method of manufacturing the semiconductor device according the embodiment of the present invention;

FIG. 7F is a sectional view showing a manufacturing step (f) in the method of manufacturing the semiconductor device according the embodiment of the present invention;

FIG. 8A is a sectional view showing a sixth structural example (6-A, 6-B) of the semiconductor device according to the embodiment of the present invention;

FIG. 8B is a plan view showing the sixth structural example (6-A) of the semiconductor device according to the embodiment of the present invention;

FIG. 8C is a plan view showing the sixth structural example (6-B) of the semiconductor device according to the embodiment of the present invention;

FIG. 9 is a sectional view showing a seventh structural example of the semiconductor device according to the embodiment of the present invention;

FIG. 10 is a sectional view showing an eighth structural example of the semiconductor device according to the embodiment of the present invention;

FIG. 11 is a sectional view showing a ninth structural example of the semiconductor device according to the embodiment of the present invention;

FIG. 12A is a sectional view showing a tenth structural example (10-A) of the semiconductor device according to the embodiment of the present invention; and

FIG. 12B is a sectional view showing the tenth structural example (10-B) of the semiconductor device according to the embodiment of the present invention.

### DESCRIPTION OF THE EMBODIMENT

A semiconductor device, a method of manufacturing the same, and a semiconductor substrate according to an embodiment of the present invention will be specifically described below with reference to the accompanying drawings.

### FIRST STRUCTURAL EXAMPLE OF THE SEMICONDUCTOR DEVICE

First, a first structural example of the semiconductor device according to the embodiment of the present invention will now be described.

FIG. 1 is a sectional view showing the first structural example of the semiconductor device according to the present embodiment. In the illustrated semiconductor device, as shown in FIG. 1, first electrodes 1 are formed on the front side of a semiconductor substrate 4, second electrodes 3 are formed on the back side of the semiconductor substrate 4, and recessed portions 6 are formed on the edge of the front side of the semiconductor substrate 4. Further, a semiconductor element 5 having a plurality of electrodes (not shown) for external connection is formed on the front side of the semiconductor substrate 4. The recessed portions 6 are formed by, for example, routing, laser machining, and so on. The base of the semiconductor substrate 4 is made of, for example, resin.

Moreover, the electrodes for external connection on the semiconductor element 5 and the first electrodes 1 of the semiconductor substrate 4 are electrically connected to each other via electrically continuous metal wires 7, for example, gold wires and the like. The front side of the semiconductor substrate 4 on which the semiconductor element 5 is mounted is entirely covered with molding resin 8 together with the semiconductor element 5 and the wires 7. Further, external electrode terminals 2 made up of solder balls and the like are connected to the second electrodes 3 of the semiconductor substrate 4. The recessed portions 6 formed on the edge of the semiconductor substrate 4 are also filled with the molding resin 8.

In this configuration, since the recessed portions 6 are formed on the edge of the semiconductor substrate 4, it is possible to increase the bonding area of the molding resin 8 and the semiconductor substrate 4, thereby improving the adhesion. Thus a resistance to a crack and exfoliation of a package can be increased and the reliability of the semiconductor device can be easily improved.

### SECOND STRUCTURAL EXAMPLE OF THE SEMICONDUCTOR DEVICE

A second structural example of the semiconductor device according to the embodiment of the present invention will now be described.

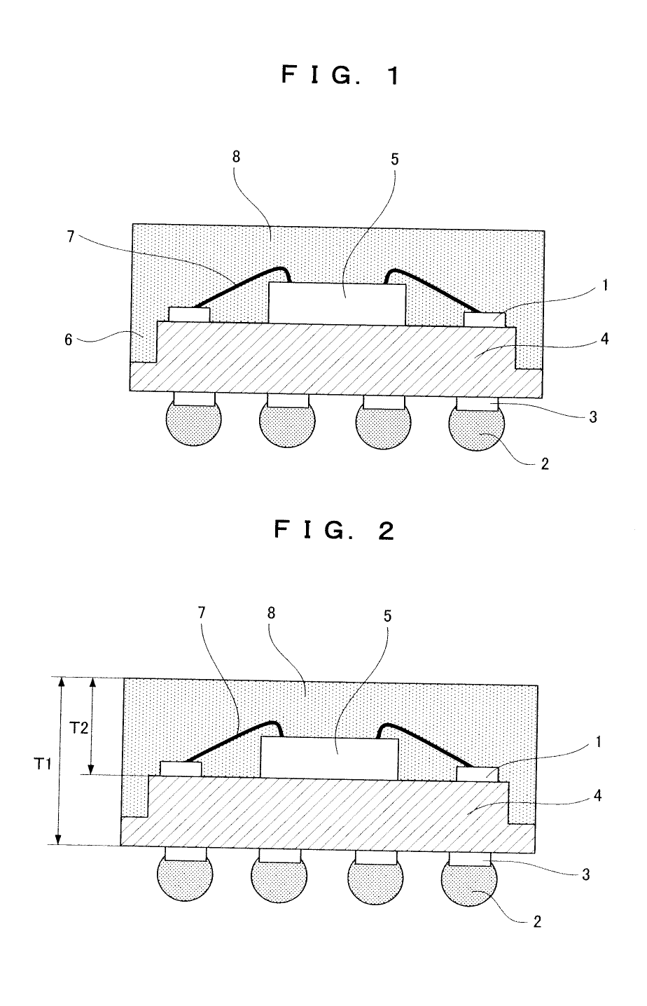

FIG. 2 is a sectional view showing the second structural example of the semiconductor device according to the present embodiment. The illustrated semiconductor device is identical in overall configuration to the semiconductor device of FIG. 1. As shown in FIG. 2, a semiconductor substrate 4 is formed such that a thickness Ti of molding resin 8 on the edge of the front side of the semiconductor substrate 4 is larger than a thickness T2 of molding resin 8 on a part other than the edge (the part includes a portion around the center of the semiconductor device).

With this configuration, the semiconductor substrate 4 can be clamped from the edge as in the first structural example, so that a resistance to a crack and exfoliation of a package can be increased and the reliability of the semiconductor device can be easily improved.

### THIRD STRUCTURAL EXAMPLE OF THE SEMICONDUCTOR DEVICE

A third structural example of the semiconductor device according to the embodiment of the present invention will now be described.

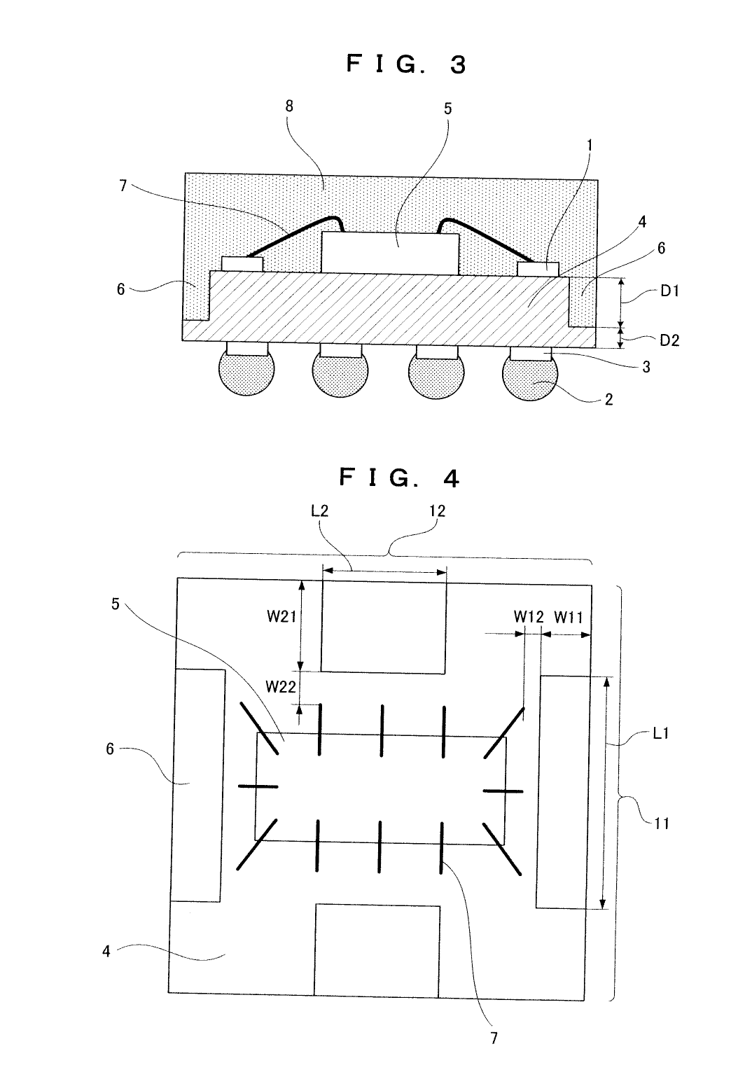

FIG. 3 is a sectional view showing the third structural example of the semiconductor device according to the present embodiment. The illustrated semiconductor device is identical in overall configuration to the semiconductor device of FIG. 1. As shown in FIG. 3, a semiconductor substrate 4 is formed such that recessed portions 6 on the edge of the semiconductor substrate 4 have a length (depth) D1 from the front side of the semiconductor substrate 4 in the thickness direction, the semiconductor substrate 4 has a thickness D2 immediately under the recessed portions 6, and the thickness D1 is larger than the thickness D2.

With this configuration, it is possible to increase the bonding area of molding resin 8 and the semiconductor substrate 4 on the edge of the semiconductor substrate 4, thereby improving the adhesion between the molding resin 8 and the semiconductor substrate 4. Thus a resistance to a crack and exfoliation of a package can be increased and the reliability of the semiconductor device can be easily improved.

### FOURTH STRUCTURAL EXAMPLE OF THE SEMICONDUCTOR EXAMPLE

A fourth structural example of the semiconductor device according to the embodiment of the present invention will now be described.

FIG. 4 is a plan view showing the fourth structural example of the semiconductor device according to the present embodiment. The illustrated semiconductor device is identical in overall configuration to the semiconductor device of FIG. 1. As shown in FIG. 4, a semiconductor substrate 4 includes recessed portions 6 which are formed along the edge of the front side of the semiconductor substrate 4 such that a length L1 on a first side 11 is different from a length L2 on a second side 12 perpendicular to the first side 11.

For example, when a semiconductor element 5 mounted on the semiconductor substrate 4 is rectangular, the semiconductor element 5 has different lengths on the first side 11 and the second side 12 of the semiconductor substrate 4 and thus different peeling forces are generated in a package.

By adjusting the lengths of the recessed portions 6 formed on the edge of the semiconductor substrate 4 to desired lengths according to a difference in peeling force, it is possible to easily achieve the configuration by which a crack of the package can be suppressed in a desired manner regardless of the size of the mounted semiconductor element 5.

Further, the semiconductor substrate 4 is formed such that on the front side of the semiconductor substrate 4, the recessed portion 6 has, on the first side 11, a length (width) W11 perpendicularly to the edge of the front side of the semiconductor substrate 4, the length W11 is larger than a distance W12 from one end of the recessed portion 6 on the central side of the front side of the semiconductor substrate 4 to the junction of a wire 7 of a first electrode 1, the recessed portion 6 has, on the second side 12, a length (width) W21 perpendicularly to the edge of the front side of the semiconductor substrate 4, and the length W21 is larger than a distance W22 from one end of the recessed portion 6 on the central side of the front side of the semiconductor substrate 4 to the junction of the wire 7 of the first electrode 1.

### FIFTH STRUCTURAL EXAMPLE OF THE SEMICONDUCTOR DEVICE

The following is a fifth structural example of the semiconductor device according to the embodiment of the present invention.

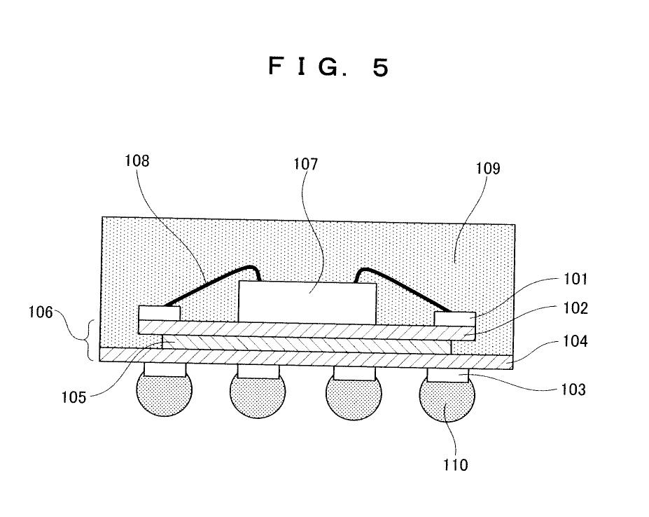

FIG. 5 is a sectional view showing the fifth structural example of the semiconductor device according to the present embodiment. As shown in FIG. 5, in the illustrated semiconductor device, a semiconductor substrate 106 has a multilayer structure made up of a first layer 102 having first electrodes 101 formed on the front side, a third layer 104 having second electrodes 103 formed on the back side, and a second layer 105 formed between the first layer 102 and the third layer 104. A semiconductor element 107 is mounted on the front side of the first layer 102 of the semiconductor substrate 106 in the multilayer structure. The base of the semiconductor substrate 106 is made of, for example, resin. In the semiconductor substrate 106, the area of the first layer 102 is larger than the area of the second layer 105 and is smaller than the area of the third layer 104. The semiconductor substrate 106 having such a multilayer structure is generally made up of a build-up substrate and is formed by stacking the layers.

Further, electrodes for external connection on the semiconductor element 107 and the first electrodes 101 on the semiconductor substrate 106 are electrically connected to each other via wires 108 such as gold wires. The semiconductor substrate 106 having the semiconductor element 107 mounted thereon is entirely covered with molding resin 109, together with the semiconductor element 107 and the wires 108. External electrode terminals 110 such as solder balls are connected to the second electrodes 103 on the back side of the semiconductor substrate 106.

Further, recessed portions formed on the edge of the semiconductor substrate 106 are also filled with the molding resin 109, and the step of the first layer 102 and the second layer 105 of the semiconductor substrate 106 having the multilayer structure is also filled with the molding resin 109 in a similar manner.

In this configuration, since the recessed portions are formed on the edge of the semiconductor substrate 106, it is possible to increase the bonding area of the molding resin 109 and the semiconductor substrate 106, thereby improving the adhesion. Thus a resistance to a crack and exfoliation of a package can be increased and the reliability of the semiconductor device can be easily improved.

### (Semiconductor Substrate and a Method of Manufacturing the Semiconductor Device)

The following will describe the semiconductor substrate and a method of manufacturing the semiconductor device according to the embodiment of the present invention.

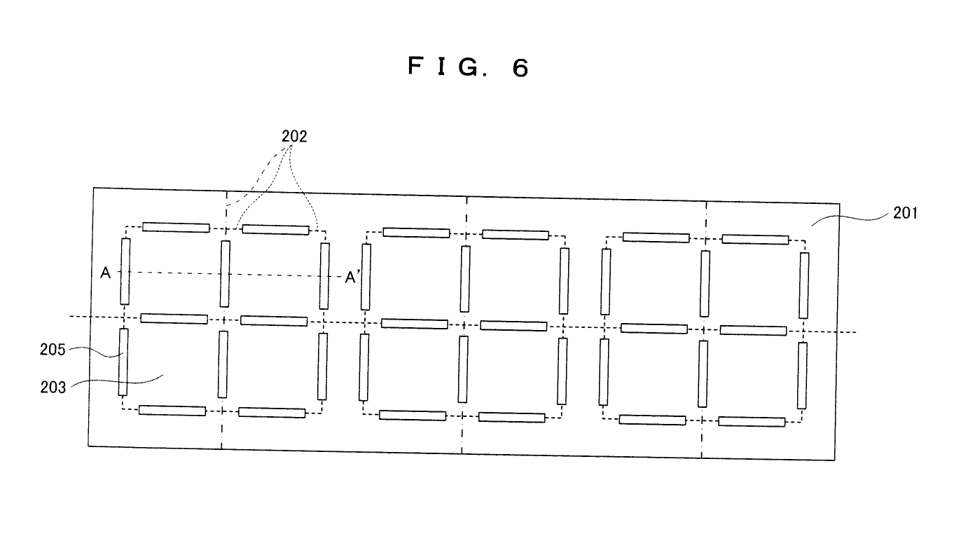

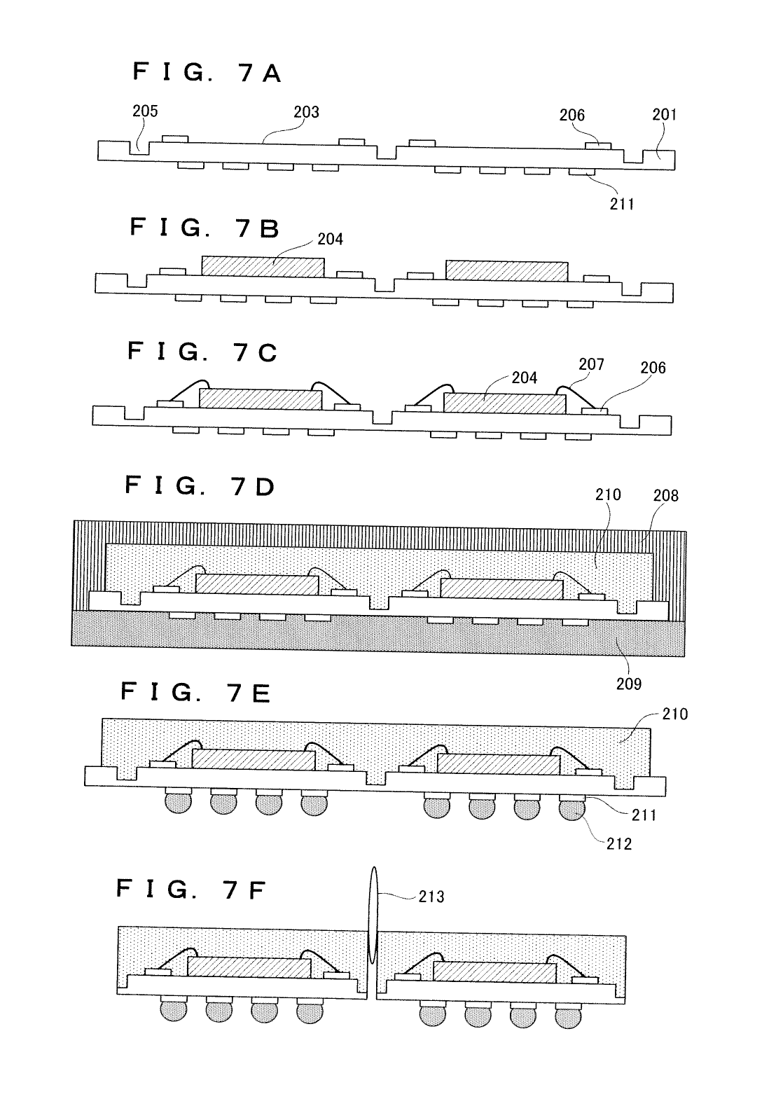

FIG. 6 is a plan view showing a structural example of the semiconductor substrate used for the method of manufacturing the semiconductor device of the present embodiment. FIGS. 7A to 7F are sectional views taken along line A-A′ of FIG. 6 and show the steps of the method of manufacturing the semiconductor device according to the present embodiment.

When the semiconductor device is manufactured, first, a plurality of semiconductor elements 204 having been cut from a wafer (not shown) into chips are prepared and a semiconductor substrate 201 for mounting the plurality of semiconductor elements 204 is prepared.

As shown in FIG. 6, the semiconductor substrate 201 has a long, thin, and flat structure. The base of the semiconductor substrate is made of, for example, resin. The semiconductor substrate 201 is divided into a plurality of semiconductor element mounting regions 203 along vertical and horizontal partition lines 202, and the semiconductor elements 204 are respectively mounted in the semiconductor element mounting regions 203. During resin molding, the front side of the semiconductor substrate 201 is molded with resin so as to simultaneously cover the four adjacent semiconductor element mounting regions 203.

As shown in FIG. 7A, the semiconductor substrate 201 has first electrodes 206 formed on the front side and second electrodes 211 formed on the back side. The second electrodes 211 are connected to external electrode terminals 212. Along the partition lines 202 for partitioning the semiconductor substrate 201 into the semiconductor element mounting regions 203, recessed portions 205 are formed on the front sides of the partition lines 202. The recessed portions 205 are formed on desired points by routing and laser machining during, for example, machining on the outside shape of the semiconductor substrate 201.

Next, on the semiconductor substrate 201 formed thus, a die bonding material and the like are applied to the central portions of the semiconductor element mounting regions 203, the semiconductor elements 204 sucked by, for example, a suction collet are mounted on the semiconductor substrate 201 as shown in FIG. 7B, and then the semiconductor substrate 201 is heated and pressurized, so that the semiconductor elements 204 are fixed on the central portions of the semiconductor element mounting regions 203 on the semiconductor substrate 201 by die bonding.

Further, as shown in FIG. 7C, a plurality of electrodes for external connection (not shown) formed on the semiconductor elements 204 and first electrodes 206 formed on the semiconductor substrate 201 are electrically connected to each other via wires 207 such as gold wires in order to electrically connect the semiconductor substrate 201 and the semiconductor elements 204 mounted on the semiconductor substrate 201.

Next, as show in FIG. 7D, the semiconductor substrate 201 having the semiconductor elements mounted thereon is set in molding dies and is molded with resin. In the resin molding, the semiconductor substrate 201 is clamped by an upper die 208 and a lower die 209 of the molding dies. At this point, at least two of the semiconductor elements 204 are disposed in each cavity formed in the upper die 208. To be specific, in the semiconductor substrate configuration of FIG. 6, the four semiconductor elements 204 are disposed in each cavity.

In a state in which the semiconductor substrate 201 is clamped thus by the molding dies, molding resin 210 is injected from the gates. Thus the semiconductor element mounting surface of the semiconductor substrate 201 is molded with the resin such that the semiconductor element mounting regions 203 are simultaneously covered with the resin together with the semiconductor elements 204 and the wires 207. At this point, the recessed portions 205 formed along the partition lines 202 of the semiconductor substrate 201 are also filled with the molding resin 210.

At this point, the semiconductor substrate 201 is present between the lower die 209 and the molding resin 210, so that the semiconductor device can be stably produced without causing resin burrs to spread to the back side of the semiconductor substrate 201.

Although a difference in expansion coefficient between the semiconductor substrate 201 and the molding resin 210 causes an internal stress, the internal stress can be dispersed by the recessed portions 205 formed along the partition lines 202. Thus it is possible to effectively prevent exfoliation of a package in the manufacturing steps.

Next, as shown in FIG. 7E, the external electrode terminals 212 such as solder balls are melted and secured by reflowing and the like on the second electrodes 211 formed on the back side of the semiconductor substrate 201.

Thereafter, as shown in FIG. 7F, the semiconductor substrate 201 and the molding resin 210 are divided along the partition lines 202 for partitioning the semiconductor substrate 201 and the molding resin 210 into the plurality of semiconductor element mounting regions 203. For example, the semiconductor substrate 201 and the molding resin 210 can be divided by setting, in a dicing machine, the semiconductor substrate 201 having been molded with the resin and moving a high speed rotating blade 213 in the vertical and horizontal directions along the partition lines 202. In the semiconductor device obtained thus after the semiconductor substrate 201 is divided, the recessed portions 205 are provided on the edge of the semiconductor substrate 201.

In this configuration, since the recessed portions 205 are formed on the edge of the semiconductor substrate 201, it is possible to increase the bonding area of the molding resin 210 and the semiconductor substrate 201, thereby improving the adhesion. Thus a resistance to a crack and exfoliation of a package can be increased.

Consequently, it is possible to eliminate a defective appearance of a product and reduce the number of steps in a manufacturing process to suppress an increase in the cost of the product while preventing a crack and exfoliation of the package to improve the reliability of the product.

In order to solve the problem of the prior art, in addition to the structural examples of the embodiment, the semiconductor device may be configured as follows:

### SIXTH STRUCTURAL EXAMPLE OF THE SEMICONDUCTOR DEVICE

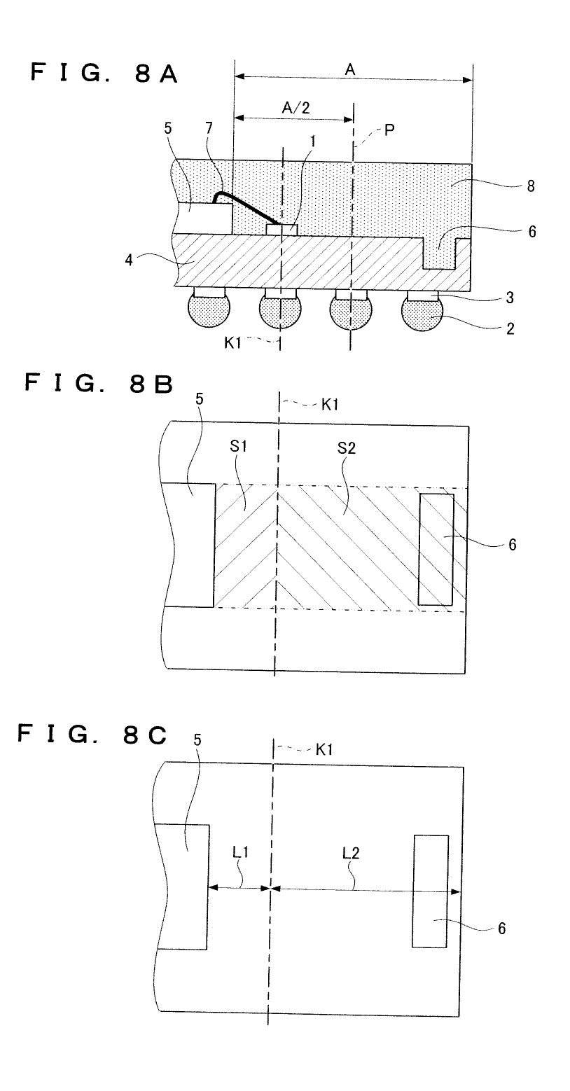

For example, as shown in FIG. 8A, a sixth structural example of the semiconductor device is configured such that first electrodes 1 are disposed on a position K1 between the center of a semiconductor substrate 4 and a central point P which is the midpoint of a distance A from the side end face of a semiconductor element 5 to the edge of the semiconductor substrate 4. In this case, as shown in FIG. 8B, the front side of the semiconductor substrate 4 is formed such that in a region which is parallel to the side width of the semiconductor element 5 and ranges from the side end face of the semiconductor element 5 to the edge of the semiconductor substrate 4 on the front side of the semiconductor substrate 4, a region surface area S2 which ranges from the first electrodes 1 on K1 to the edge of the semiconductor substrate 4 and includes the inner wall surfaces of recessed portion 6 is larger than a region surface area S1 ranging from the side end face of the semiconductor element 5 to the first electrodes 1 on K1.

Further, as shown in FIG. 8C, the front side of the semiconductor substrate 4 is formed such that in a direction substantially perpendicular to the side of the semiconductor element 5 from the side end face of the semiconductor element 5 to the edge of the semiconductor substrate 4 on the front side of the semiconductor substrate 4, a surface distance L2 which ranges from the first electrodes 1 on K1 to the edge of the semiconductor substrate 4 and includes the inner wall surfaces of the recessed portion 6 is longer than a surface distance L1 from the side end face of the semiconductor element 5 to the first electrodes 1 on K1.

### SEVENTH STRUCTURAL EXAMPLE OF THE SEMICONDUCTOR DEVICE

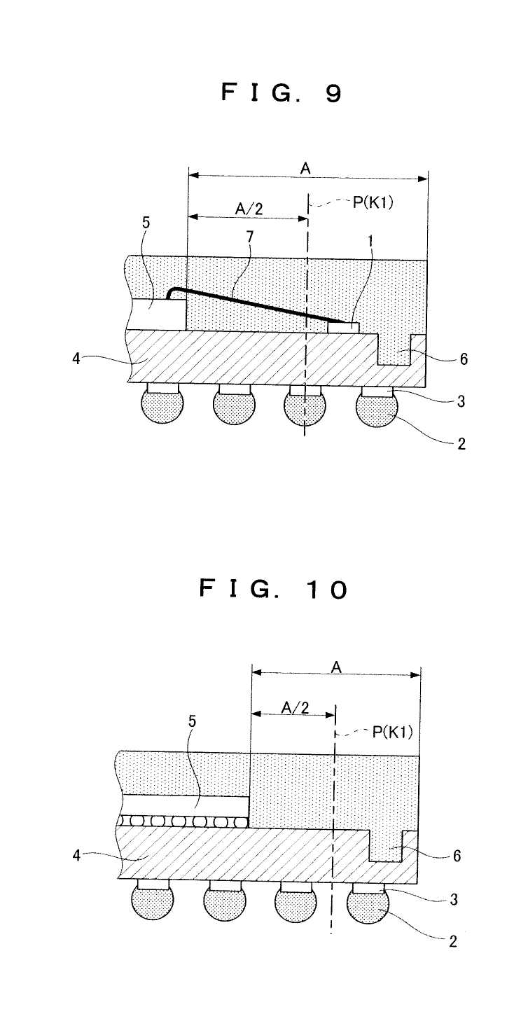

For example, as shown in FIG. 9, a seventh structural example of the semiconductor device is configured such that first electrodes 1 are disposed between the edge of a semiconductor substrate 4 and a central point P which is the midpoint of a distance A from the side end face of a semiconductor element 5 to the edge of the semiconductor substrate 4. In this case, as in FIG. 8B, the front side of the semiconductor substrate 4 is formed such that in a region which is parallel to the side width of the semiconductor element 5 and ranges from the side end face of the semiconductor element 5 to the edge of the semiconductor substrate 4 on the front side of the semiconductor substrate 4, a region surface area S2 which ranges from the central point P(K1) to the edge of the semiconductor substrate 4 and includes the inner wall surfaces of a recessed portion 6 is larger than a region surface area S1 from the side end face of the semiconductor element 5 to the central point P(K1). In this configuration, the central point P is regarded as K1 of FIGS. 8A to 8C.

Moreover, as in FIG. 8C, the front side of the semiconductor substrate 4 is formed such that in a direction substantially perpendicular to the side of the semiconductor element 5 from the side end face of the semiconductor element 5 to the edge of the semiconductor substrate 4 on the front side of the semiconductor substrate 4, a surface distance L2 which ranges from the central point P(K1) to the edge of the semiconductor substrate 4 and includes the inner wall surfaces of the recessed portion 6 is longer than a surface distance L1 ranging from the side end face of the semiconductor element 5 to the central point P(K1). In this configuration, the central point P is regarded as K1 of FIGS. 8A to 8C.

### EIGHTH STRUCTURAL EXAMPLE OF THE SEMICONDUCTOR DEVICE

In the structural examples of the embodiment, the semiconductor element 5 is electrically connected to the first electrodes 1 via the wires 7 by wire bonding. The present invention is not limited to this configuration. The present invention can be similarly implemented by the semiconductor element 5 mounted on the semiconductor substrate 4 by other techniques in a state in which electric signals can be inputted and outputted to and from the first electrodes 1 on the semiconductor substrate 4. For example, the semiconductor device may be configured as follows:

As shown in FIG. 10, a flip-chip semiconductor element 5 may be mounted around the center of the front side of the semiconductor substrate 4, instead of the semiconductor element mounted by wire bonding. In this case, the first electrodes 1 electrically connected to the semiconductor element 5 are formed in the mounting region of the semiconductor element 5 on the front side of the semiconductor substrate 4. The front side of the semiconductor substrate 4 is formed as in the semiconductor device of FIG. 9.

Further, as in the case of the flip-chip semiconductor element, the present invention can be implemented by a semiconductor element 5 capable of inputting and outputting electric signals in a noncontact manner (not shown) on the semiconductor substrate 4 by means of light (e.g., laser light) and electromagnetic waves such as radio waves (high-frequency waves). Also in this case, the front side of the semiconductor substrate 4 is formed as in the semiconductor device of FIG. 9.

### NINTH STRUCTURAL EXAMPLE OF THE SEMICONDUCTOR DEVICE

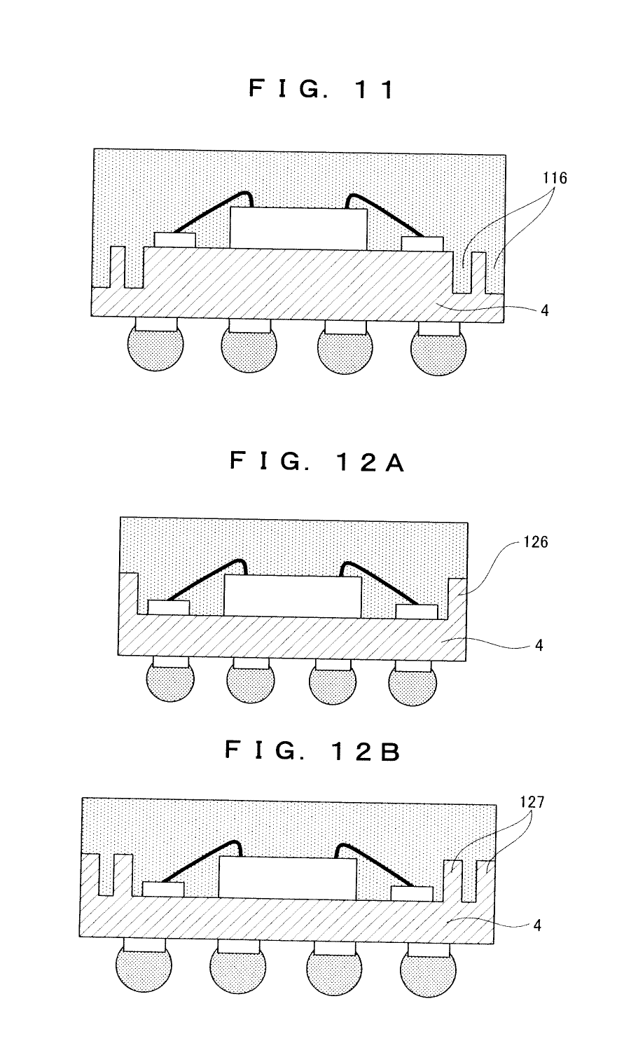

In the structural examples of the embodiment, the recessed portions 6 each of which has a groove are formed on the edge of the front side of the semiconductor substrate 4. As shown in FIG. 11, recessed portions 116 each of which has, e.g., two (may be more than two) grooves may be formed. In this case, adhesion to molding resin 8 can be further improved on the edge of the semiconductor substrate 4.

### TENTH STRUCTURAL EXAMPLE OF THE SEMICONDUCTOR DEVICE

In the structural examples of the embodiment, the recessed portions each of which has at least one groove are formed on the edge of the front side of the semiconductor substrate 4. For example, as shown in FIG. 12A, convex portions 126 each of which has a rib may be formed on the semiconductor substrate 4. Alternatively, as shown in FIG. 12B, convex portions 127 each of which has two (may be more than two) ribs may be formed on the semiconductor substrate 4. Also in this case, adhesion to molding resin 8 can be further improved on the edge of the semiconductor substrate 4 as in the semiconductor device of FIG. 11.

What is claimed is:

1. A semiconductor device in which a semiconductor element having a plurality of electrodes for external connection is mounted on a front side of a semiconductor substrate having first electrodes formed on the front side and second electrodes formed on a back side,
the electrodes for external connection on the front side of the semiconductor element and the first electrodes are electrically connected to each other,
the front side of the semiconductor substrate is entirely covered with molding resin, and
a plurality of external electrode terminals are connected to the second electrodes,
wherein the semiconductor substrate has recessed portions formed on an edge of the front side of the semiconductor substrate.

2. A semiconductor device in which a semiconductor element having a plurality of electrodes for external connection is mounted on a front side of a semiconductor substrate having first electrodes formed on the front side and second electrodes formed on a back side,
the electrodes for external connection on the front side of the semiconductor element and the first electrodes are electrically connected to each other,
the front side of the semiconductor substrate is entirely covered with molding resin, and
a plurality of external electrode terminals are connected to the second electrodes,
wherein the semiconductor substrate has an edge formed on the front side of the semiconductor substrate such that the molding resin has a larger thickness on the edge of the semiconductor substrate than on other portions.

3. A semiconductor device in which a semiconductor substrate having a multilayer structure made up of a first layer having first electrodes formed on a front side, a third layer having second electrodes formed on a back side, and a second layer disposed between the first layer and the third layer,
a semiconductor element having a plurality of electrodes for external connection is mounted on the front side of the first layer,
the electrodes for external connection on a front side of the semiconductor element and the first electrodes are electrically connected to each other,
the semiconductor substrate has a front side entirely covered with molding resin, and
a plurality of external electrode terminals are connected to the second electrodes,
wherein the first layer has an area larger than an area of the second layer and smaller than an area of the third layer in the semiconductor substrate.

4. The semiconductor device according to claim 1, wherein along the edge of the front side of the semiconductor substrate, the recessed portions have different lengths on a first side and a second side perpendicular to the first side.

5. The semiconductor device according to claim 1, wherein the recessed portion of the semiconductor substrate has a length from the front side of the semiconductor substrate in a thickness direction and the length is larger than a thickness of a portion immediately under the recessed portion in the semiconductor substrate.

6. The semiconductor device according to claim 1, wherein the recessed portion of the semiconductor substrate has, on the front side of the semiconductor substrate, a length perpendicularly to the edge of the front side of the semiconductor substrate and the length is larger than a distance from one end of the recessed portion on a central side of the front side of the semiconductor substrate to an electrical junction of the first electrodes with the electrodes for external connection.

7. A method of manufacturing a semiconductor device, comprising the steps of:
mounting semiconductor elements in a plurality of semiconductor element mounting regions of a semiconductor substrate partitioned by partition lines into the semiconductor element mounting regions for mounting the semiconductor elements;
molding a semiconductor element mounting surface of the semiconductor substrate with resin so as to simultaneously cover at least two of the semiconductor element mounting regions; and
dividing the semiconductor substrate into semiconductor devices by dividing the semiconductor substrate into the plurality of semiconductor element mounting regions along the partition lines,
wherein the method further comprises the step of forming, along the partition lines, recessed portions on the partition lines on a front side of the semiconductor substrate before the resin molding.

8. A semiconductor substrate comprising, for collective molding of semiconductor devices, first electrodes formed on a front side, second electrodes formed on a back side and connected to external electrode terminals, and a plurality of semiconductor element mounting regions,
wherein the semiconductor substrate further comprises recessed portions formed on partition lines on the front side of the semiconductor substrate, along the partition lines for partitioning the semiconductor substrate into the plurality of semiconductor element mounting regions.

9. A semiconductor device in which a semiconductor element having a plurality of electrodes for external connection is mounted on a front side of a semiconductor substrate having first electrodes formed on the front side and second electrodes formed on a back side,
the electrodes for external connection on the semiconductor element and the first electrodes are electrically connected to each other,
the front side of the semiconductor substrate is entirely covered with molding resin, and
a plurality of external electrode terminals are connected to the second electrodes,
wherein in a case where the first electrodes are disposed between a center of the semiconductor substrate and a central point of a side end face of the semiconductor element and an edge of the semiconductor substrate,
the front side of the semiconductor substrate is formed such that in a region which is parallel to a side width of the semiconductor element and ranges from the side end face of the semiconductor element to the edge of the semiconductor substrate on the front side of the semiconductor substrate,
a region surface area ranging from the first electrodes to the edge of the semiconductor substrate is larger than a region surface area ranging from the side end face of the semiconductor element to the first electrodes.

10. A semiconductor device in which a semiconductor element having a plurality of electrodes for external connection is mounted on a front side of a semiconductor substrate having first electrodes formed on the front side and second electrodes formed on a back side,
the electrodes for external connection on the semiconductor element and the first electrodes are electrically connected to each other,
the front side of the semiconductor substrate is entirely covered with molding resin, and
a plurality of external electrode terminals are connected to the second electrodes,
wherein in a case where the first electrodes are disposed between an edge of the semiconductor substrate and a central point of a side end face of the semiconductor element and the edge of the semiconductor substrate,
the front side of the semiconductor substrate is formed such that in a region which is parallel to a side width of the semiconductor element and ranges from the side end face of the semiconductor element to the edge of the semiconductor substrate on the front side of the semiconductor substrate,
a region surface area ranging from the central point to the edge of the semiconductor substrate is larger than a region surface area ranging from the side end face of the semiconductor element to the central point.

11. A semiconductor device in which a semiconductor element having a plurality of electrodes for external connection is mounted on a front side of a semiconductor substrate having first electrodes formed on the front side and second electrodes formed on a back side,
the electrodes for external connection on the semiconductor element and the first electrodes are electrically connected to each other,
the front side of the semiconductor substrate is entirely covered with molding resin, and
a plurality of external electrode terminals are connected to the second electrodes,
wherein in a case where the first electrodes are disposed between a center of the semiconductor substrate and a central point of a side end face of the semiconductor element and an edge of the semiconductor substrate,
the front side of the semiconductor substrate is formed such that in a direction substantially perpendicular to a side of the semiconductor element from the side end face of the semiconductor element to the edge of the semiconductor substrate on the front side of the semiconductor substrate,
a surface distance from the first electrodes to the edge of the semiconductor substrate is longer than a surface distance from the side end face of the semiconductor element to the first electrodes.

12. A semiconductor device in which a semiconductor element having a plurality of electrodes for external connection is mounted on a front side of a semiconductor substrate having first electrodes formed on the front side and second electrodes formed on a back side,
the electrodes for external connection on the semiconductor element and the first electrodes are electrically connected to each other,
the front side of the semiconductor substrate is entirely covered with molding resin, and
a plurality of external electrode terminals are connected to the second electrodes,
wherein in a case where the first electrodes are disposed between an edge of the semiconductor substrate and a central point of a side end face of the semiconductor element and the edge of the semiconductor substrate,
the front side of the semiconductor substrate is formed such that in a direction substantially perpendicular to a side of the semiconductor element from the side end face of the semiconductor element to the edge of the semiconductor substrate on the front side of the semiconductor substrate,
a surface distance from the central point to the edge of the semiconductor substrate is longer than a surface distance from the side end face of the semiconductor element to the central point.
